(19) United States
(12) Patent Application Publication
(10) Pub. No.: US 2005/0146853 A1
(43) Pub. Date: Jul. 7, 2005

(54) Heat dissipating device

(75) Inventor: Zi-Li Zhang, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-cheng City (TW)

(21) Appl. No.: 10/873,083

(22) Filed: Jun. 21, 2004

(30) Foreign Application Priority Data
Jan. 7, 2004 (CN) 200420014787.9

(51) Int. Cl. H05K 7/20

(52) U.S. Cl. 361/703

(57) ABSTRACT

A heat dissipating device (10) includes a hollow post (20) defining a plurality of grooves (28) in a longitudinal direction thereof, a base (22) extending from the post and located at one end of said longitudinal direction, a plurality of fins (30) radially extending from the post. Each fin has a heat absorbing portion extending through a corresponding groove of the post and a heat dissipating portion opposing the heat absorbing portion. A combining member (40) is filled in the post and integrated with the heat absorbing portions of the fins and the base.

### TECHNICAL FIELD

The present invention relates to heat dissipating devices, and particularly to a heat dissipating device which can efficiently dissipate heat from an electronic component.

### BACKGROUND

As computer technology continues to advance, electronic components such as central processing units (CPUs) of computers are being made to provide faster operational speeds and greater functional capabilities. When a CPU operates at high speed in a computer enclosure, its temperature frequently increases greatly. It is desirable to dissipate the generated heat quickly, for example, by using a heat sink attached to the CPU in the enclosure. This allows the CPU and other electronic components in the enclosure to function within their normal operating temperature ranges, thereby assuring the quality of data management, storage and transfer.

Conventionally, a heat sink comprises a base for contacting an electronic component and a plurality of fins extending from the base. The heat sink is integrally formed by extrusion or die-casting in a mold. However, the ratio of the height of the fins to the distance between the fins is limited by the mold technology. Generally, the ratio of the height of the fins to the distance between the fins is smaller than 12. Thus, heat dissipating area of the heat sink is limited.

Subsequently, heat sinks using fold fins were developed. FIG. 6 shows a conventional heat sink 50 comprising a column 70 and a plurality of fold fins 60. The fins 60 are formed by continuously folding a thin plate. An opening 64 is formed between and surrounded by the fins 60 for extension of the column 70. The fins 60 are attached to the outer circumferential surface of the column 70 by thermal grease. The column 70 is mounted to an electronic component 90 by a clip 80, for transferring heat from the electronic component 90 to the fins 60. However, in attaching the fins 60 to the colomn 70, the thermal grease is prone to be scraped off. As a result, heat transferring effect from the column 70 to the fins 60 will be reduced. Furthermore, the fins 60 are attached on the outer circumferential surface of the column 70 by means of their folded edges. The contacting area between the column 70 and the folded edges of the fins 60 is small and generally is only about one half of the area of the outer circumferential surface of the column 70. Heat dissipating effect of the heat sink 50 is therefore limited.

Thus, an improved heat dissipating device which overcomes the above-mentioned problem is desired.

### SUMMARY OF THE INVENTION

Accordingly, an object of the present invention is to provide a heat dissipating device which can efficiently dissipate heat from a heat generating component.

To achieve the above-mentioned object, a locking device in accordance with a preferred embodiment of the present invention comprises a heat receiving member, a heat transferring member extending from the heat receiving member, and a heat dissipating member comprising a plurality of discrete fins surrounding the heat transferring member. Each fin comprises a heat absorbing portion extending into the heat transferring member and a heat dissipating portion extending away from the heat transferring member.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is a front elevational view of a body of a heat dissipating device in accordance with a preferred embodiment of the present invention;

FIG. 2 is top plan view of the body of FIG. 1;

FIG. 3 is a front elevational view of a fin of the heat dissipating device;

FIG. 4 is a top plan view of the heat dissipating device;

FIG. 5 is a front elevational view of the heat dissipating device; and

FIG. 6 is an isometric veiw of a conventional heat sink together with a clip and an electronic component.

### DETAILED DESCRIPTION OF A PREFERRED EMBODIMENT

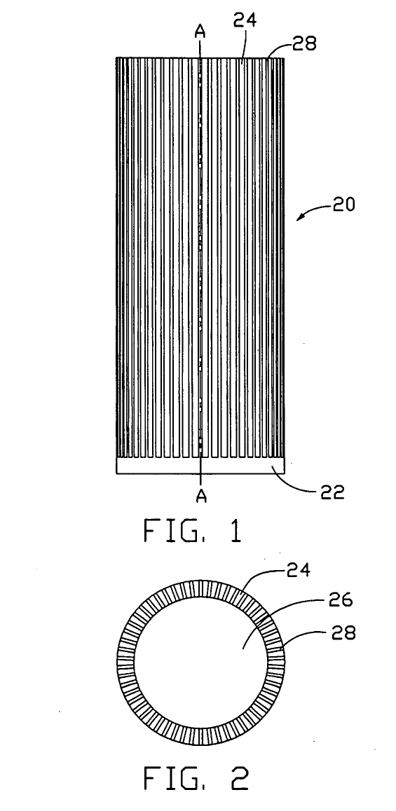

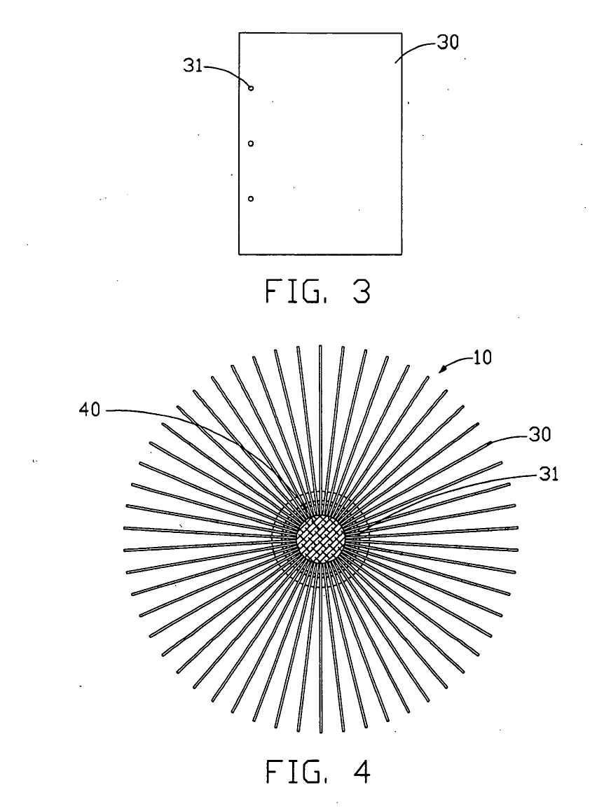

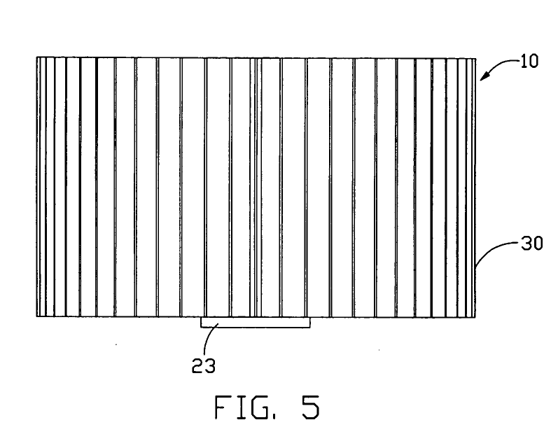

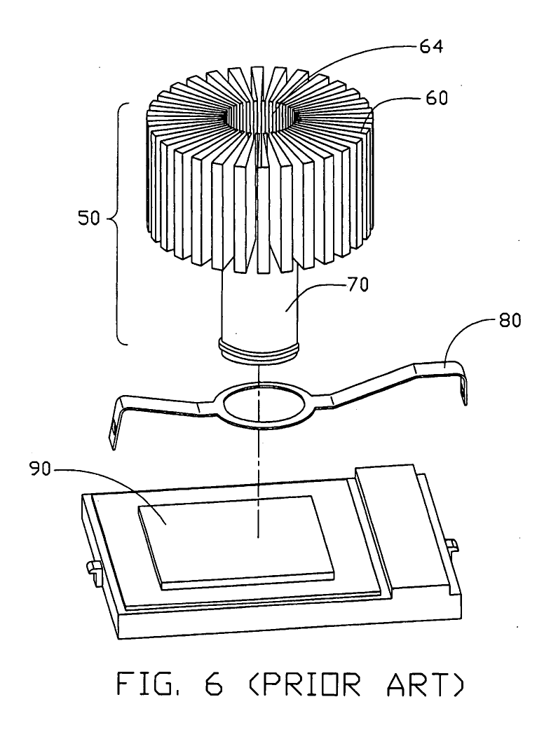

FIGS. 1-5 shows a heat dissipating device 10 in accordance with a preferred embodiment of the present invention. The heat dissipating device 10 comprises a body 20 and a plurality of fins 30.

The body 20 comprises a base 22 and a hollow post 24 extending upwardly from the base 22. The base 22 has a circular configuration. The post 24 has a column configuration and defines a central hole 26 in a longitudinal direction thereof, spaning from the top surface to the bottom surface of the post 24. A circumferential wall is therefore formed surrounding the hole 26. A plurality of grooves 28 is defined radially in the circumferential wall of the post 24 in the longitudinal direction of the post 24 and equally spaning from the top surface to the bottom surface of the post 24.

Each of the fins 30 has a rectangular configuration. Each fin 30 comprises a heat absorbing portion at one side thereof and a heat dissipating portion at an opposite side thereof. A plurality of projections 31 is formed on the heat absorbing portion of the fin 30.

In assembly, the fins 30 are interferentially inserted into the grooves 28 of the post 24 in an up-to-down direction. The heat absorbing portions of the fins 30 extend into the hole 26 of the post 24 and free ends thereof are located at a circle. The projections 31 abut against the inner circumferential surface of the post 24 in the hole 26, for preventing the fins 30 from moving out of the grooves 28. A combining member 40 made of heat conductive material, such as thermal grease, molten copper, or molten aluminum etc., is filled in the hole 26 of the post 20. After the combining member 40 is cooled the combining member 40 is integrated with the fins 30 and the base 22 of the body 20. Thus, the heat dissipating device 10 is completely made.

In the present invention, the base 22 acts as a heat receiving member for contacting a heat generating component (not shown) to absorb heat therefrom. The post 24 and the combining member 40 cooperatively act as a heat transferring member for transferring the heat from the heat receiving member 22 to the absorbing portions of the fins 30. The fins 30 act as a heat dissipating member for dissipating heat absorbed from the heat transferring member to ambient air.

In the present invention, the fins 30 are discrete from each other and independently attached to the post 24. The fins 30 are independently formed by stamping a thin plate. The ratio of the height of the fins 30 to the distance between the fins 30 is not technically limited. Furthermore, it is convenient to fill the combining member 24 into the hole 26. Moreover, the fins 30 extend into the post 20 to allow the heat absorbing portions thereof to contact the combining member 40. As a result, contacting area between the heat dissipating member and the heat transferring member is greatly increased and heat dissipating effect of the heat dissipating device 10 is consequently improved.

It is understood that the invention may be embodied in other forms without departing from the spirit thereof. Thus, the present example and embodiment is to be considered in all respects as illustrative and not restrictive, and the invention is not to be limited to the details given herein.

1. A heat dissipating device comprising:
a hollow post defining a plurality of grooves extending in a longitudinal direction thereof;
a heat receiving member extending from the post and located at one end of the post in said longitudinal direction;
a plurality of fins radially extending from the post, each fin having a heat absorbing portion extending through a corresponding groove of the post and a heat dissipating portion opposing the heat absorbing portion; and
a combining member filled in the post and integrated with the heat absorbing portions of the fins and the heat receiving member.

2. The heat dissipating device as claimed in claim 1, wherein the post has a column configuration and defines a hole in a center thereof, the combining member being filled in said hole.

3. The heat dissipating device as claimed in claim 2, wherein said hole extends through the post in said longitudinal direction.

4. The heat dissipating device as claimed in claim 3, wherein each fin forms at least one projection abutting an inner circumferential surface of the post in said hole.

5. The heat dissipating device as claimed in claim 4, wherein free ends of the heat absorbing portions of the fins are concentric with each other.

6. The heat dissipating device as claimed in claim 1, wherein the fins are discrete from each other and each fin has a rectangular shape.

7. A heat dissipating device comprising:
a heat receiving member;
a heat transferring member extending from the heat receiving member; and
a heat dissipating member comprising a plurality of discrete fins surrounding the heat transferring member, each fin having a heat absorbing portion extending into the heat transferring member and a heat dissipating portion extending away from the heat transferring member.

8. The heat dissipating device as claimed in claim 7, wherein the heat transferring member comprises a post with a hole formed in a center thereof and a circumferential wall surrounding the hole.

9. The heat dissipating device as claimed in claim 8, wherein said circumferential wall defines a plurality of grooves in a longitudinal direction thereof, the heat absorbing portion of each fin extending through a corresponding groove into the hole.

10. The heat dissipating device as claimed in claim 9, wherein the heat transferring member further comprises a combining member filled in the hole and integrating with the heat absorbing portions of the fins and the heat receiving member.

11. The heat dissipating device as claimed in claim 10, wherein each fin forms at least one projection abutting an inner circumferential surface of the post in said hole.
